(19) United States
(12) Patent Application Publication
(10) Pub. No.: US 2008/0296743 A1
(43) Pub. Date: Dec. 4, 2008

(54) Semiconductor device and method for fabricating the same

(75) Inventor: Dae Young Kim, Suwon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/152,880

(22) Filed: May 15, 2008

(30) Foreign Application Priority Data
May 28, 2007 (KR) 10-2007-0051312

(51) Int. Cl. H01L 23/58; H01L 21/469

(52) U.S. Cl. 257/637; 438/761; 257/E23.167

(57) ABSTRACT

The present invention relates to a semiconductor device, and a method for fabricating a semiconductor device, which involves an oxide-nitride-oxide stack in a silicon-oxide-nitride-oxide-silicon device. Barrier characteristics of an upper blocking dielectric layer and/or a lower tunneling dielectric layer on upper and lower sides of a charge trapping dielectric layer are improved, so as to maintain holding characteristics of charges trapped in the charge trapping dielectric layer, making it possible to improve reliability of a semiconductor device containing the same.

The present application claims the benefit under 35 U.S.C. §119 of Korean Patent Application No. 10-2007-0051312, filed on May 28, 2007, which is hereby incorporated by reference in its entirety.

### BACKGROUND OF THE INVENTION

1. Field of the Invention

The present invention relates to a semiconductor device, and in particular to a semiconductor device and a method for fabricating the same, which can fabricate a silicon-oxide-nitride-oxide-silicon (SONOS) device.

2. Discussion of the Related Art

Generally, semiconductor memory devices may be largely divided into a volatile memory and a non-volatile memory. Most volatile memories are a RAM, such as a dynamic RAM (DRAM) and a static RAM (SRAM), that have characteristics that can input or preserve data during an application of a supply power but cannot preserve data due to the loss of data when the power supply is interrupted. Most non-volatile memories are a type of read only memory (ROM) and have characteristics that can preserve data even when the power supply is not applied.

Non-volatile memories may be classified into floating gate type devices and metal insulator semiconductor type devices, in which two kinds of dielectric layers are stacked in a double- or a triple-layer stack.

The memory of the floating gate system uses a potential well to implement memory characteristics. A representative example of the memory of the floating gate series is an EEPROM structure having a tunnel oxide, which is widely used as a current flash memory or electronically erasable programmable ROM (EEPROM).

On the other hand, the MIS devices use a trap layer existing in a dielectric layer-semiconductor interface, a dielectric layer-dielectric interface, or a dielectric bulk layer to perform a memory function. A representative example of the MIS series is a metal and/or silicon-oxide-nitride-oxide (ONO)— semiconductor structure, which is also widely used as a current flash memory or EEPROM.

FIG. 1 is a vertical cross-sectional view showing a memory with a SONOS structure.

Generally, the non-volatile memory cell with the SONOS structure includes ONO films 2 to 4, formed of dielectric layers sequentially stacked on an upper surface of an active region of a semiconductor substrate 1, and gate-electrodes formed on an upper surface of the oxide film 4. And, a source/drain junction is formed within a semiconductor substrate 1. The ONO films 2 to 4, which are the dielectric layers, perform a role of storing charges in the SONOS structure.

Referring to FIG. 1, the ONO films 2 to 4 are formed by sequentially stacking a tunneling dielectric layer 2, a charging or charge trapping dielectric layer 3, and a blocking dielectric layer 4 on the upper surface of the active region of the semiconductor substrate 1. As one example, the tunneling dielectric layer 2 and the blocking dielectric layer 4 are silicon oxide (SiO₂) films, and the charging dielectric layer 3 is a silicon nitride (Si₃N₄) film.

In the non-volatile memory with the conventional SONOS structure, the charges are tunneled through the tunneling dielectric layer 2 so that they are trapped in the silicon nitride film, if programming voltage is applied to the gate electrode. The trapped charges can be lost through the upper blocking dielectric layer 4 or the lower tunneling dielectric layer 2. Thereby, the data holding characteristic may degrade to cause a reliability problem in the device.

More specifically, a method for fabricating the non-volatile memory with the conventional or general SONOS structure uses high temperature oxidation for forming the blocking dielectric layer 4 and a thermal oxide for the tunneling dielectric layer. The oxide films thus formed may have a limitation with regard to preventing the loss of charges trapped in the nitride film. In the viewpoint of evaluating the charge holding characteristics of the non-volatile memory, charges trapped in the nitride film may be lost in the process of performing repeated programming and erase operations.

### SUMMARY OF THE INVENTION

The present invention proposes to solve the above problems. In particular, it is an object of the present invention to provide a semiconductor device and a method for fabricating the same which is suitable for improving data holding characteristics of an ONO film so as to improve reliability of the device. More particularly, the device may be a nonvolatile memory device.

It is another object of the present invention to provide a semiconductor device and a method for fabricating the same which is suitable for improving the barrier characteristics of a blocking dielectric layer and/or a tunneling dielectric layer in an ONO stack so as to maintain the charge holding characteristics of the charging (or charge trapping) dielectric layer.

In order to achieve these and/or other objects, there is provided a semiconductor device according to the present invention including: a charge trapping nitride film; and a barrier film comprising a plasma nitration film on at least one of an upper side and a lower side of the nitride film.

Preferably, the semiconductor device further includes an oxide film on the upper surface of the nitride film, between the nitride film and the barrier film. Preferably, it further includes another oxide film on the lower side of the nitride film, where the barrier film is between the nitride film and the other oxide film.

In order to achieve these and/or other objects, there is provided a semiconductor device according to the present invention including: a tunneling dielectric layer on a semiconductor substrate; a charge barrier film on an upper surface of the tunneling dielectric layer; a charge trapping dielectric layer on an upper of the charge barrier film; a blocking dielectric layer on an upper surface of the charge trapping dielectric layer; and a charge barrier film on an upper surface of the blocking dielectric layer.

Preferably, the tunneling dielectric layer comprises a thermal oxide film, grown or formed on the semiconductor substrate using wet oxidation. Preferably, the blocking dielectric layer is a high temperature oxide film, formed on the charge trapping dielectric layer using high temperature oxidation. Preferably, the charge barrier films may be formed by a plasma nitration process.

Preferably, each of the tunneling dielectric layer, the charge trapping dielectric layer, and the blocking dielectric layer may have a thickness of from 16 to 25 Å, from 45 to 75 Å and from 60 to 100 Å, respectively.

In order to achieve these and/or other objects, a method for fabricating a SONOS device structure according to the present invention may include the steps of: forming a dielectric layer on a semiconductor substrate using oxide film deposition or thermal oxide growth; and performing a plasma nitration process on the dielectric layer.

Preferably, the dielectric layer may be formed on the semiconductor substrate using wet oxidation and/or high temperature oxidation, and the dielectric layer may be formed after performing the plasma nitration. Preferably, the method may further comprise forming a second dielectric layer, and the two dielectric layers may have different thicknesses.

In order to achieve these and/or other objects, there is provided a method for fabricating a semiconductor device according to the present invention including the steps of: forming a first oxide film on a semiconductor substrate; forming a charge barrier film by performing a plasma nitration process on the first oxide film; forming a nitride film on the plasma nitration film; forming a second oxide film on the nitride film; and forming a charge barrier film by performing a plasma nitration process on the second oxide film.

Preferably, the first oxide film may be formed on the semiconductor substrate using wet oxidation, and the second oxide film may be formed on the nitride film using high temperature oxidation.

### BRIEF DESCRIPTION OF THE DRAWINGS

FIG. 1 is a vertical cross-sectional view showing a memory with a general SONOS structure.

FIG. 2 is a vertical cross-sectional view showing a memory with a SONOS structure according to one embodiment of the present invention.

FIG. 3 is a vertical cross-sectional view showing a memory with a SONOS structure according to another embodiment of the present invention.

FIGS. 4a to 4d are vertical cross-sectional views for explaining a process for fabricating the memory with the SONOS structure according to embodiments of the present invention.

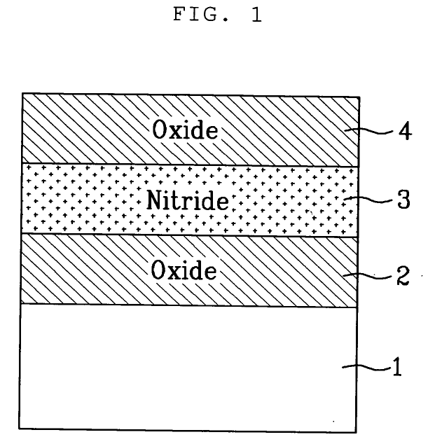

### DETAILED DESCRIPTION OF THE EMBODIMENTS

Other objects, features, and advantages of the present invention will be apparent through the detailed description of embodiments with reference to the accompanying drawings.

Hereinafter, the configuration and action of embodiments of the present invention will be described with reference to the accompanying drawings. The configuration and action of the present invention shown in the drawings and described with reference to the drawings will be described as at least one embodiment; however, the technical idea and the core configuration and action of the present invention are not limited thereto.

A semiconductor device according to the present invention comprises a memory with a SONOS structure. In particular, the memory according to the present invention is more preferably a non-volatile memory with the SONOS structure. Therefore, a basic structure in the semiconductor device according to the present invention is an ONO film, which comprises stacked oxide and nitride dielectric layers, formed on an upper surface of an active region. A gate electrode is generally formed on an upper surface of the ONO film. Also, source/drain junctions may be formed in the semiconductor substrate, in regions adjacent to the gate electrode.

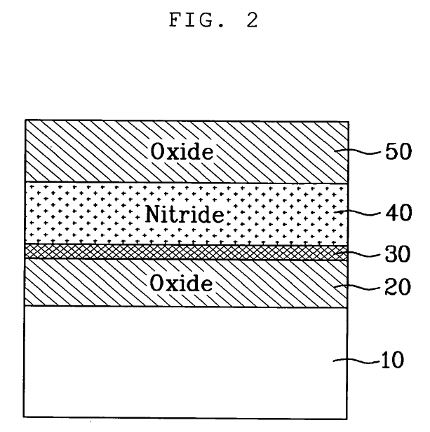

FIGS. 2 and 3 are vertical cross-sectional views of a SONOS structure according to embodiments of the present invention. Referring to FIGS. 2 and 3, an ONO film comprising a tunneling dielectric layer 20, a charge trapping nitride film 40, and a blocking dielectric layer 50 will be described. Therefore, a first oxide film 20 corresponds to the tunneling dielectric layer, the nitride film 40 corresponds to the charge trapping dielectric (or nitride) film, and the second oxide film 50 corresponds to the blocking dielectric layer.

In particular, in the present invention, a barrier film 30 is formed by performing a plasma nitration process on an upper surface of the first oxide film 20 (or a lower side of the nitride film) before the charge trapping nitride film 40 is formed. Also, referring now to FIG. 3, a barrier film 60 is formed by performing the plasma nitration process on an upper side of the nitride film 40 after the charge trapping nitride film 40 is formed. Preferably, the barrier film 60 is formed on an upper side of the second oxide film 50 (for blocking).

Also, in the present invention, the barrier films 30, 60 are formed on the upper side and lower side of the nitride film 40 before and after the charge trapping nitride film 40 is formed. In certain embodiments, the first barrier film 30 is formed on the-first (tunneling) oxide film 20 and the second barrier film 60 is formed on the second (blocking) oxide film 50.

FIG. 2 shows an example of forming the barrier film by performing plasma nitration processing on the tunneling oxide film 20. This forms the barrier film 30 on the oxide film 20 on the semiconductor substrate 10, and then the charge trapping nitride film 40 is formed on the barrier film 30 so that the barrier film 30 is between the nitride film 40 and the oxide film 20.

In an example of a nonvolatile memory device using the structure of FIG. 2, a gate electrode (not shown) is formed on the second oxide film 50 after the second oxide film 50 is formed.

FIG. 3 shows an example of forming the blocking oxide film 50 over the barrier film 30 formed in FIG. 2, as well as on the upper surface of the nitride film 40, and then forming another barrier film 60 by further performing plasma nitration processing on the blocking oxide film 50. A memory device with the SONOS structure according to FIG. 3 may comprise the first (tunneling) oxide film 20 formed on the semiconductor substrate 10, a first barrier film 30 formed on the first oxide film 20, the charge trapping nitride film 40 formed on the first barrier film 30, the second (blocking) oxide film 40 formed on the nitride film 40, and the second barrier film 60 formed on the second oxide film 40.

Preferably, the semiconductor substrate 10 is (or comprises) a bare and/or single-crystal Si substrate.

The first oxide film 20 may be formed on the semiconductor substrate 10 by wet oxidation (e.g., thermal growth of SiO₂ on Si). The first oxide film 20 is preferably formed at a thickness of from 16 to 25 Å. In particular, the first oxide film 20 preferably has a thickness of 20 Å.

The first barrier film 30 is formed by performing a plasma nitration process on the first oxide film 20. At this time, as preferable conditions for performing plasma nitration processing, a processing power (e.g., power for or supplied to the plasma nitration processing equipment) is from 100 to 2000 Watts, 200 to 1600 Watts, or 400 to 1200 Watts (and in one example, about 800 Watts), the pressure is from 1 to 100 mtorr, 2 to 50 mtorr, or 5 to 20 mtorr (and in one example, about 10 mtorr), nitrogen gas (N₂) flux or inflow is from 50 to 2000 sccm, 100 to 1600 sccm, or 100 to 1000 sccm (and in one example, about 500 sccm), and the processing time is from 10 to 480 seconds, 30 to 300 seconds, or 45 to 240 seconds (and in one example, about 75 seconds). Also, other nitrogen source gases can be used in the plasma nitration process, such as a nitrogen oxide (e.g., N₂O, NO, NO₂, N₂O₃, etc.), nitrogen hydride (e.g., NH₃, N₂H₄, etc.), or a combination thereof (with or without nitrogen gas), but nitrogen gas (N₂) is preferred. Consequently, the first barrier film 30 generally comprises a nitrided silicon oxide film (e.g., silicon oxynitride or silicon oxide in which “dangling” silicon and/or oxygen atoms [e.g., Si and/or O atoms that do not have a complete set of 4 or 2 covalent bonds to other atoms, respectively] are bound to nitrogen).

The nitride film 40 formed on the first barrier film 30 may have a thickness of from 45 to 75 Å. Preferably, the nitride film 40 formed on the first barrier film 30 has a thickness of about 60 Å. Preferably, the second oxide film 50 is or comprises a high temperature oxide film formed using high temperature oxidation. Preferably, the second oxide film has a thickness of from 60 to 100 Å. In particular, the second oxide film may have a thickness of about 80 Å.

Finally, the second barrier layer 60 is formed by performing the plasma nitration process on the second oxide film 50. At this time, the conditions for performing the plasma nitration processing are preferably the same as those applied to forming the first barrier film 30. Meanwhile, the first barrier film 30 and the second barrier film 60 may have the same thickness. However, the first oxide film 20, the nitride film 20, the second oxide film 50 preferably have different thicknesses.

Also, in an example of FIG. 3, the gate electrode is formed on the upper of the second barrier film 60 after the second barrier film 60 is formed.

Memory devices with a SONOS structure according to the present invention may be fabricated by forming the dielectric layers using an oxide film deposition technique, and then performing plasma nitration processing on the deposited dielectric layers. The barrier characteristics of the present ONO films are improved by either or both barrier films formed by plasma nitration processing. The barrier characteristics of the ONO films are improved and may prevent the loss of trapped charges, thereby improving data preservation and/or retention properties. At this time, the dielectric layers may be formed using oxide deposition for either tunneling or blocking dielectric layers in the ONO films. However, in the present invention, oxide films formed using wet oxidation or high temperature oxidation are preferable.

Hereinafter, a fabrication of the memory with the SONOS structure according to the present invention will be described in more detail.

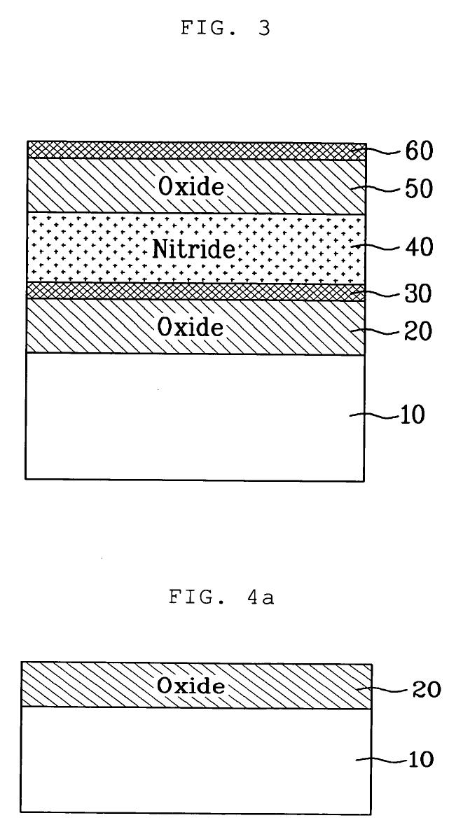

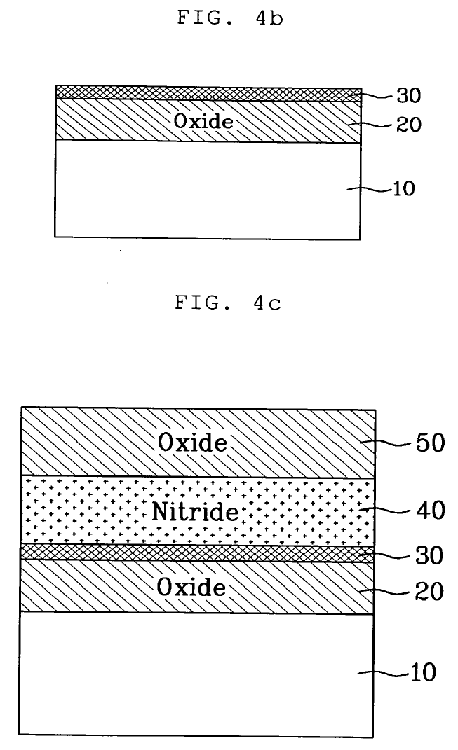

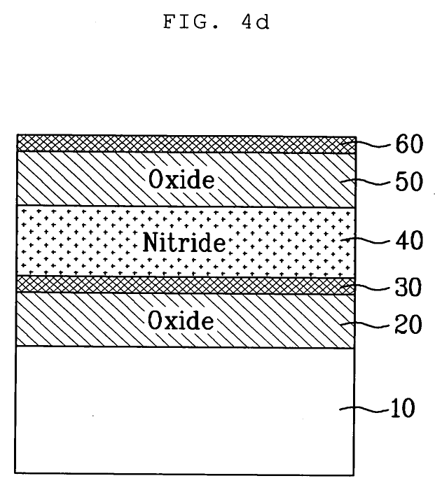

FIGS. 4a to 4d are vertical cross-sectional views for explaining an exemplary process for fabricating the SONOS structure according to the present invention.

As shown in FIG. 4a, the first oxide film 20, which is the tunneling dielectric layer, may be formed at a thickness of about 20 Å on the upper surface of the active region of the silicon substrate 10 (for example, a bare, single-crystal Si substrate) using wet oxidation.

Next, as shown in FIG. 4b, the barrier film 20, which is the charge barrier film for preventing the loss of the trapped charges, is formed by performing the plasma nitration process on the upper surface of the formed first oxide film 20. The plasma nitration processing conditions may be the same as or similar to those described elsewhere herein (e.g., a power of about 800 watts, a pressure of about 10 mtorr, a nitrogen gas flux of about 500 sccm, and a processing time of about 75 seconds).

After the plasma nitration processing, the dielectric layer 40 for storing charges is formed at a thickness of about 60 Å, and the high temperature (blocking) oxide film 50 is formed on the nitride film 40 at a thickness of about 80 (FIG. 4c).

Finally, the barrier film 60, which is another charge barrier film for preventing the loss of the trapped charges, is formed by plasma nitration processing on the upper surface of the high temperature oxide film 50 (FIG. 4d).

Preferably, the barrier films formed by plasma nitration processing are thinner or have a smaller thickness than the thickness of the oxide films 20 or 50, or the nitride film 40, of the ONO films.

It can be apparent to those skilled in the art that many changes and modifications can be made within the scope of the present invention. Therefore, the technical scope of the present invention is not limited to the described contents, but is defined by the appended claims.

As described above, the present invention forms one or more charge barrier films through plasma nitration processing before and/or after formation of a charge trapping dielectric layer to improve the barrier characteristics against loss of the trapped charges through the upper blocking dielectric layer or the lower tunneling dielectric layer. In other words, the charge retention of (or holding characteristics of charges trapped in) the charge trapping dielectric layer is improved. In particular, the loss of charges trapped in the nitride film can be minimized, even in the course of performing repeated programming and erase operations. Consequently, degradation of the data retention characteristics may be minimized, reduced or removed, making it possible to improve reliability of the semiconductor device.

What is claimed is:

1. A semiconductor device including:
a charge trapping nitride film; and
a barrier film comprising a plasma nitration film on at least one of an upper side and a lower side of the nitride film.

2. The semiconductor device according to claim 1, further including an oxide film between the nitride film and the barrier film on the upper side of the nitride film.

3. The semiconductor device according to claim 1, further including an oxide film on the lower side of-the nitride film, the barrier film being between the nitride film and the oxide film.

4. A semiconductor device including:
a tunneling dielectric layer on a semiconductor substrate;
a first charge barrier film on an upper surface of the tunneling dielectric layer;
a charge trapping dielectric layer on an upper surface of the first charge barrier film;
a blocking dielectric layer on an upper surface of the charge trapping dielectric layer; and
a second charge barrier film on an upper surface of the blocking dielectric layer.

5. The semiconductor device according to claim 4, wherein the tunneling dielectric layer comprises a thermal oxide film.

6. The semiconductor device according to claim 4, wherein the blocking dielectric layer comprises a high temperature oxide film.

7. The semiconductor device according to claim 4, wherein the charge barrier films are formed by a plasma nitration processing

8. The semiconductor device according to claim 4, wherein the tunneling dielectric layer has a thickness of from 16 to 25 A.

9. The semiconductor device according to claim 8, wherein the charge trapping dielectric layer has a thickness of from 45 to 75 Å.

10. The semiconductor device according to claim 9, wherein the blocking dielectric layer has a thickness of from 60 to 100 Å.

11. The semiconductor device according to claim 4, wherein each of the first and second charge barrier films comprise a silicon oxynitride.

12. A method for fabricating a structure for a SONOS device including the steps of:
forming a dielectric layer on a semiconductor substrate; and
performing a plasma nitration process on the dielectric layer.

13. The method according to claim 12, wherein forming the dielectric layer comprises wet oxidation.

14. The method according to claim 12, wherein forming the dielectric layer comprises high temperature oxidation, after performing the plasma nitration process.

15. The method according to claim 12, further comprising forming a charge trapping layer, wherein the dielectric layer has a different thickness from that of the charge trapping layer.

16. A method for fabricating a SONOS structure for a semiconductor device, including the steps of:
forming a first oxide film on a semiconductor substrate;
forming a first charge barrier film by performing a plasma nitration process on the first oxide film;
forming a nitride film on the first charge barrier film;
forming a second oxide film on the nitride film; and
forming a second charge barrier film by performing a second plasma nitration process on the second oxide film.

17. The method according to claim 16, wherein forming the first oxide film comprises wet oxidation.

18. The method according to claim 16, wherein forming the second oxide film comprises high temperature oxidation.

19. The method according to claim 16, wherein performing the first plasma nitration process comprises exposing the first oxide film to a plasma comprising a first nitrogen source gas for a length of time of at least 10 seconds.

20. The method according to claim 19, wherein performing the second plasma nitration process comprises exposing the second oxide film to a plasma comprising a second nitrogen source gas for a length of time of at least 10 seconds.
